(19) United States
(12) Patent Application Publication
(10) Pub. No.: US 2009/0283746 A1
(43) Pub. Date: Nov. 19, 2009

(54) LIGHT-EMITTING DEVICES WITH MODULATION DOPED ACTIVE LAYERS

(75) Inventors: Christopher L. Chua, San Jose, CA (US); Zhihong Yang, Sunnyvale, CA (US)

Correspondence Address: MARGER JOHNSON & MCCOLLOM/PARC, 210 MORRISON STREET, SUITE 400, PORTLAND, OR, 97204, US

(73) Assignee: PALO ALTO RESEARCH CENTER INCORPORATED, Palo Alto, CA (US)

(21) Appl. No.: 12/121,431

(22) Filed: May 15, 2008

(51) Int. Cl. H01L 29/06; H01S 5/00; H01L 21/20

(52) U.S. Cl. 257/13; 372/44.01; 438/492; 257/E33.005; 257/E29.005; 257/E21.04

(57) ABSTRACT

A semiconductor light emitting device has an n-type layer, a p-type layer, and a light-emitting active layer arranged between the p-type layer and the n-type layer, the active layer having alternating regions of doped and undoped materials. A double heterojunction light emitting device has a bulk active layer having doped portions alternating with undoped portions. A method of manufacturing a light emitting device includes forming a first layer arranged on a substrate, growing an active layer, selectively adding impurities at predetermined times during the growing of the active layer, and forming a second layer arranged on the active layer.

### GOVERNMENT FUNDING

This invention was made with Government support under Contract No. 70NANB3H3052 issued by the National Institute of Standards and Technology. The Government has certain rights in this invention.

### BACKGROUND

Light-emitting semiconductor devices such as light-emitting diodes (LEDs) and diode lasers typically utilize undoped multiple quantum wells as the active layer. A quantum well is essentially an energy well that confines charge particles that normally move in three dimensions to two dimensions. The confinement promotes efficient recombination of electrons and holes, emitting the energy generated by the recombination as light. This confinement generally results from constructing layers of specific materials, such as a layer of gallium arsenide (GaAs) sandwiched between aluminum arsenide (AlAs).

Multiple quantum wells provide high optical gain, making them attractive as active layers for light-emitting semiconductor devices. However, quantum wells have very small volumes and therefore operate with high carrier densities. Higher carrier densities may lead to loss mechanisms such as Auger recombination, in which energy, instead of being emitted as light, is transferred to another carrier essentially ‘wasting’ the energy to heat instead of producing light. Auger recombination is a sensitive function of carrier density because it increases as the cube power of the carrier concentration in the material.

One option to decrease carrier concentration employs bulk active layers. Bulk active layers have larger volumes and operate with much lower carrier densities. However, the thicker layer can lead to higher device voltages. This is especially true of devices containing high levels of aluminum, such as aluminum gallium nitride devices and indium aluminum gallium nitride devices.

Additionally, some LEDs, such as those in a gallium nitride (GaN) system, suffer from the effects of built-in electric fields that develop across the p-side and n-side of the device. This field prevents efficient carrier injection into the quantum well layers of the active layer, in turn reducing the efficiency of the LED, and increasing the necessary current to inject carriers.

### BRIEF DESCRIPTION OF THE DRAWINGS

FIG. 1 shows an example of layers in a multiple quantum well device.

FIG. 2 shows an embodiment of a double heterojunction device having a bulk active layer.

FIG. 3 shows a graph of light versus current curves of an array of double heterojunction devices.

FIG. 4 shows a graph of light versus current for various dimensioned devices.

FIG. 5 shows a graph of voltage versus current various dimensioned devices.

FIG. 6 shows an embodiment of a multiple quantum well device having doped barrier layers.

FIG. 7 shows an embodiment of a doped barrier layer.

FIG. 8 shows an embodiment of a method of manufacturing a light-emitting device.

### DETAILED DESCRIPTION OF THE EMBODIMENTS

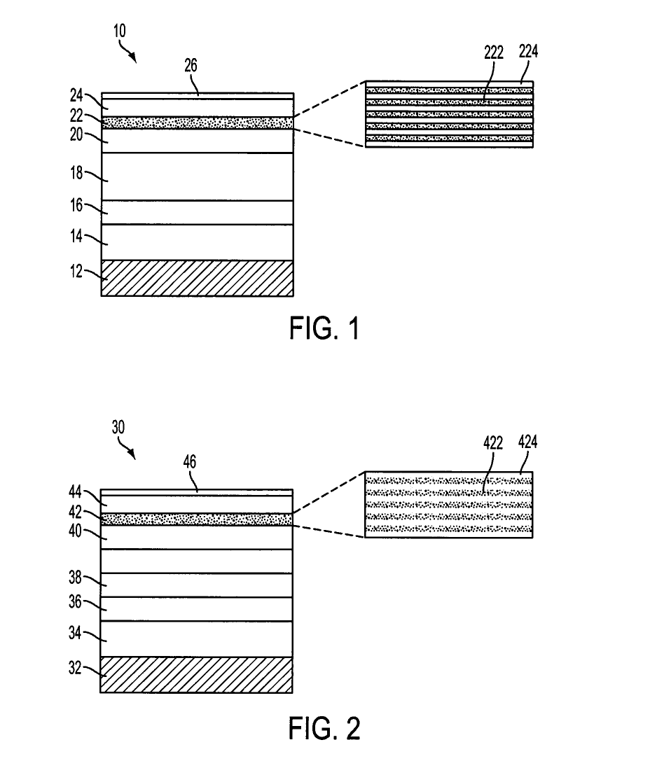

FIG. 1 shows a light emitting device 10 using an active layer having multiple quantum wells. A substrate 12 has formed upon it a template layer 14. The template layer generally determines the suitable material system and associated range of the emitted light that can be designed. The example of FIG. 1 has an aluminum nitride template, being directed for ultraviolet (UV) light emission. In this particular device a strain reduction region 16 is provided to alleviate some of the strain that may occur at the interfaces of the different materials.

LEDs and other light emitting devices generally consist of a p-type material interfacing with an n-type material. In the example of FIG. 1, the n-type material layer 18 is the n-contact for electrical connection outside the device. The top layer 26 provides the p-type electrical connection outside the device. These layers are typically biased, the n-contact layer being negatively biased and the p-contact layer being positively biased.

Layer 20 of FIG. 1 is the electron injection layer. This region may consist of more than one layer. Alternatively, the layer may be absent, with electrons being injected into the n-contact layer instead. Layer 24 is the hole injection layer or layers. This region may also consist of more than one layer.

The barrier layers 20 and 24 sandwich the active layer 22. The active layer actually consists of a multi-layered structure, with alternative layers of different materials, or materials with the same basic elements, but having differing concentrations, alternating as barrier layers and wells. The quantum wells emit light as the constrained particles give off their energy as light as they move down to lower energy bands. For example, the barrier layers such as 224 may be Al_{0.26}Ga_{0.74}N and the wells such as 222 may be Al_{0.23}Ga_{0.77}N.

While several different materials and thicknesses may be used in these devices, some specific examples may be given throughout this discussion. These examples are only for ease of discussion and are in no way intended to limit the scope of application of the invention, and no such limitation should be implied. For example, the substrate 12 may be sapphire, with the template layer 14 being aluminum nitride (AlN). The strain reduction region may be aluminum gallium arsenide (AlGaN) having the relationship Al_{0.70}Ga_{0.30}N. The n-contact layer may be of Al_{0.31}Ga_{0.69}N doped with silicon (designated as :Si). The electron injection layer may be Al_{0.33}Ga_{0.67}N:Si. The hole injection layer 24 may be Al_{0.33}Ga_{0.67}N, doped with magnesium. This particular structure is then capped with a p-contact layer, in this example GaN:Mg⁺.

In addition to many possible variations in both the materials and the concentrations or relationships between them, the dimensions of the various layers may also be varied to achieve different effects or for different applications. In this particular example, the buffer layer 14 may be 1000 nanometers (nm), the strain reduction region 16 76 nm, the n-contact layer being a 1500 nm layer 18 and an 810 nm layer 20 as the electron injection layer.

The active layer would be 90 nm, comprised of barrier layers of over 10 nm alternating with well layers of just over 5 nm. The hole injection layer would be 240 nm and the p-contact layer approximately 20 nm. All of these dimensions are approximate and may be varied depending upon the materials and the applications. This particular device is a light-emitting diode that emits light in the deep ultraviolet (deep-UV) range of wavelengths, approximately 320 nm wavelengths.

However, the higher carrier densities resulting from the smaller volume in the quantum wells are undesirable for some applications. The term carrier density refers to the number of carriers divided by the volume. When the volume is smaller, the carrier density is higher. The higher carrier densities may result in operation of loss mechanisms, such as Auger recombination, that reduce the efficiency of the light emitting device.

Using a bulk active layer, where the active layer is formed from one material, rather than the alternating layers of different materials, increases the volume, which in turn reduces the carrier density. An issue with using bulk active layers is that they can be resistive and require high voltages to operate. However, it is possible to alter the bulk active layer to lower the operating voltage. FIG. 2 shows one example of such a device.

For comparison purposes the device 30 of FIG. 2 is structured very similarly to the device of FIG. 1, having a substrate 32, a template layer 34, a strain reduction region 36, an n-contact layer 38, electron injection layer 40, an active layer 42, a hole injection layer 44, and a p-contact layer 46. It is also a deep-UV light emitting diode (LED).

However, the active layer is a bulk active layer, rather than a layer of alternating materials. Within the bulk active layer, impurities have been introduced periodically during the growth of the active layer to produce doped regions and undoped regions. One difference between the different regions in the bulk active layer and the previous device is that the bulk active layer consists of the same basic material. In this instance, the material is In_{0.01}Al_{0.26}Ga_{0.73}N. It has loosely defined regions that are doped alternating with regions that are not doped.

In the example of FIG. 2, the undoped regions or portions may be approximately 15 nm thick and the doped portions may be slightly more than 2 nm thick. The ratio of thicknesses between the undoped and doped regions may be four or five to one, unlike the previous device in which the ratio between the barrier and well layers was approximately two to one. In the embodiment of FIG. 2, the doped regions are kept very thin because these regions have deep levels in their energy band that would degrade light emission.

As mentioned above, the doped regions are not separate layers of different materials. They are doped regions in the same bulk material. This periodic doping may be achieved by ‘modulated doping’ where an impurity is introduced during growth of the active layer for short intervals of some predetermined time. The doping alleviates the typical high voltage levels that existed in bulk active layer light emitting devices.

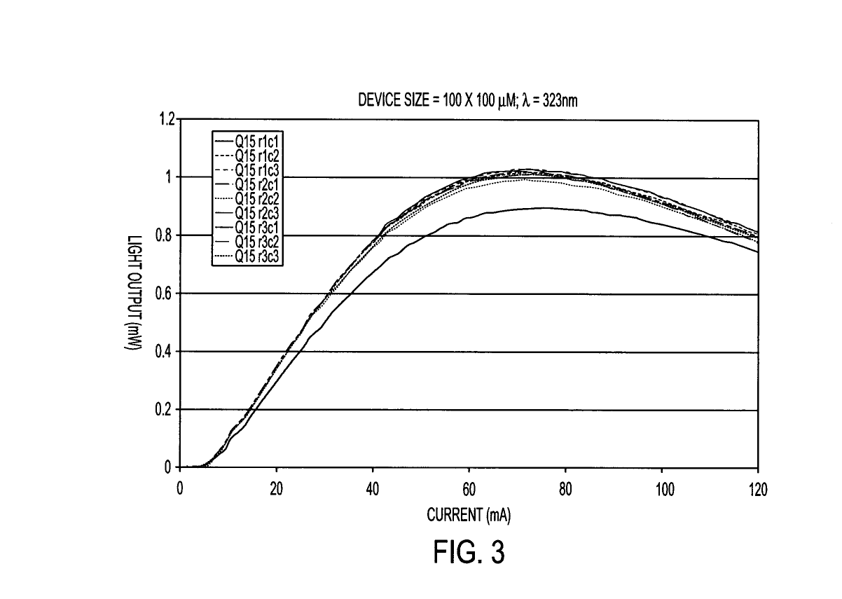

The doping profile does not necessarily have to be periodic. It can, for example, have more doping sections near the n-side of the structure than near the p-side. The doping level of one region may also vary from the doping levels of other regions, resulting in differently doped regions. FIGS. 3-5 shows some resulting light versus current and voltage versus current experimental results.

FIG. 3 shows the measured light versus current curves of an array of 100 micrometer square deep-UV LEDs having the modulated doped region. In the capture of the data shown in FIG. 3, the array was operating with over 1 mW of output power when tested in wafer form without packaging or heat sinking.

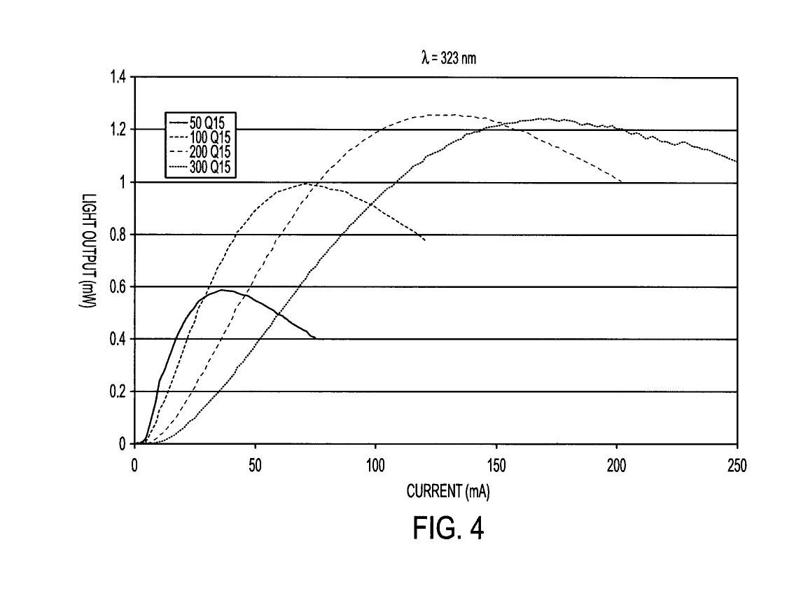

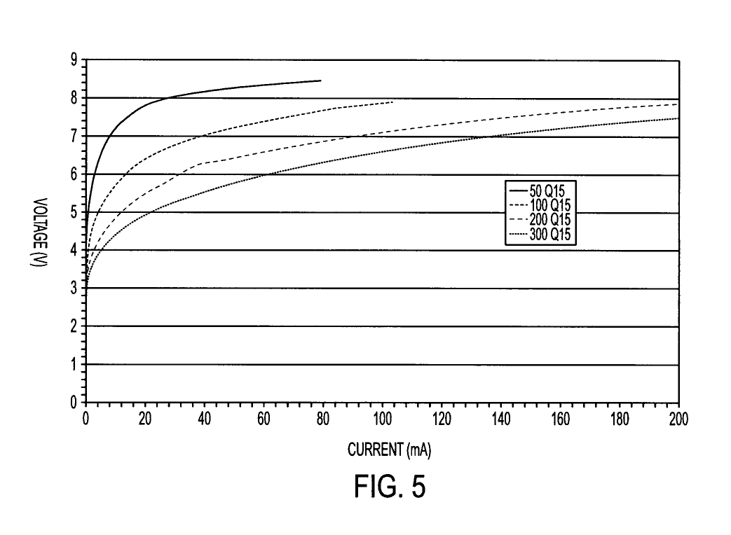

FIG. 4 shows light versus current characteristics of 50 micron, 100 micron, 200 micron, and 300 micron square devices made from the same wafer. FIG. 5 shows the corresponding voltage versus current characteristics for the same arrays. It should be noted that the voltages range from 3 to just over 8 volts to attain the necessary current to cause the device to emit light, reasonable levels when one considers that they are being applied to bulk layers, rather than to quantum wells. Prior to implementations of this invention, use of a bulk layer generally required much higher voltage levels.

These results arise from the introduction of what is essentially an impurity into the bulk active layer. Impurities in the layers of light emitting devices are generally undesirable. In the above embodiment, however, the impurity, or dopant, allows the bulk active layer to be activated at much lower voltages. The effect on voltages may also carry over to quantum well devices.

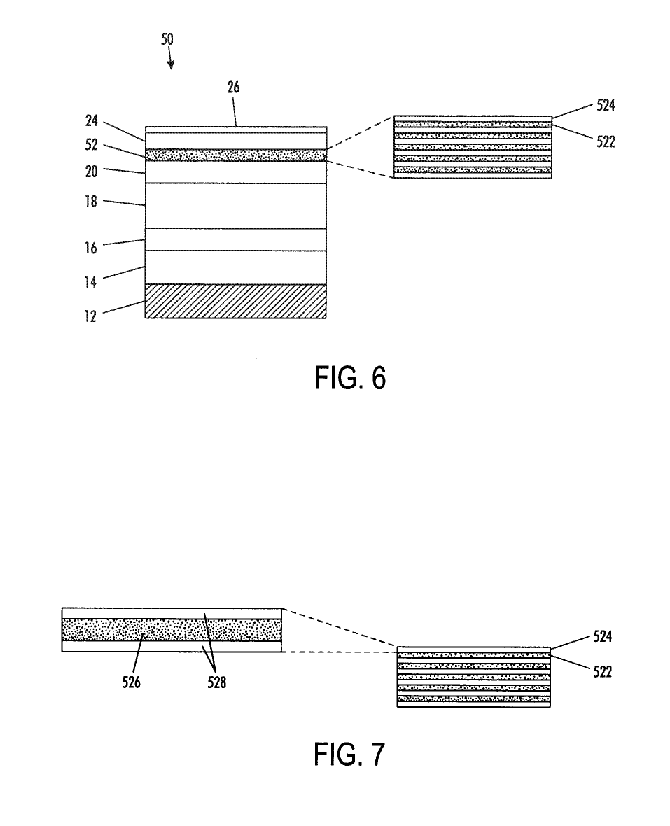

Another issue that may arise in p-n junction, quantum well devices results from the electric field formed between the p-contact layer and the n-contact layer. This field impedes the efficient injection of carriers into the electron injection layer and reduces the overall efficiency of the device. However, it is possible to dope the barrier layers of quantum well devices and utilize the effects of the dopants to reduce this field strength and increase the efficiency of these devices. An example of such a device is shown in FIG. 6.

The device of FIG. 6 has many similarities to the device of FIG. 1, for comparison purposes. The application of these techniques and embodiments are not restricted to this type of device and should not be seen as limiting the scope of the invention as claimed. However, the device 50 of FIG. 6 has a different active layer than the one in FIG. 1.

In FIG. 6, the device 50 has an active layer 52 that may or may not be comprised of the same materials as the basic materials as that previously discussed with regard to FIG. 1. The quantum well layers, such as 522, may be Al_{0.23}Ga_{0.77}N. While the barrier layers such as 524 may be Al_{0.26}Ga_{0.74}N, they would also be doped, such as with silicon (Si).

In one embodiment, only a portion of each barrier is doped, that portion being a center portion with half the thickness of the barrier. The doped center portion is sandwiched between two undoped sections of barrier materials each a quarter the thickness of the entire barrier. This is shown in FIG. 7, with the barrier 524 shown in an exploded view to see the doped region 526 sandwiched between undoped regions 528 within the barrier layer 524.

Also, in a multiple quantum well active layer, some barriers may be left completely undoped. In one embodiment, the last barrier in a multiple quantum well active layer nearest the p-side is left undoped. The doping of the barrier layers would alter the strength of the electric field across the p-n junction, and allow for more efficient electron injection and therefore more efficient devices.

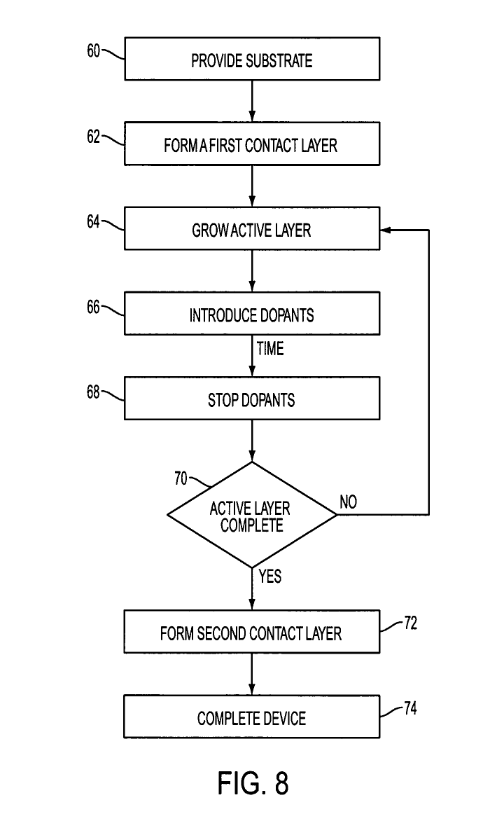

In the embodiments above, the operation of the device is improved by the addition of an impurity or dopant during the growth of the active layer. This may occur in both double heterojunction bulk active layer devices and in multiple quantum well devices. Although the discussion above focuses on n-type doping using Si impurities, p-type doping using p-type impurities such as Mg is also possible. One can envision a process for manufacture that may result in these devices. One such embodiment of such a process is shown in FIG. 8.

In FIG. 8, a substrate is provided at 60. Typically, the substrate may be sapphire or gallium nitride (GaN). Variations of the applications and types of light emitting devices may result in variations in the existence and nature of the buffer and strain relief layers. A first layer, such as the n-type layer is formed on the substrate at 62, either with or without the intervening layers shown in FIGS. 1, 2 and 6. Formation may take one of many forms including chemical vapor deposition (CVD), molecular beam epitaxy (MBE), wet deposition processes, etc.

At 64, the growth of the active layer begins, typically through CVD or MBE. Throughout the growth process a dopant or dopants are introduced at 66 for some predetermined period of time. The dopants are then stopped at 68, while the active layer continues to grow. This cycle continues until the active layer is complete at 70.

The process of introducing dopants may take many forms. For a bulk active layer device, an example may be embodied as a device with a sapphire substrate having n-doped regions within the active layer. One embodiment may specifically dope with silicon. During growth of the active layer, a periodic or modulated timed release of silane gas occurs to introduce silicon into the active layer. In a specific embodiment, the timing of the silane gas is controlled such that the doped regions are approximately 2⅓ nm thick, and the undoped regions are approximately 15 nm thick, with a total active layer thickness of approximately 90 nm.

In the embodiments resulting in a multiple quantum well device, the dopants are introduced during the growth of the barrier layers that are to be doped. As mentioned above, not all of the barrier layers may be doped. Doping the quantum well layers would more than likely be undesirable, as such doping would introduce defect levels and degrade device operating efficiency. In a particular example using silicon, a silane gas may be introduced during the formation of each of the barrier layers, resulting in each barrier layer being doped with silicon. The silane gas may be turned on partially through the process of forming the barrier layer and turned off before the barrier layer is formed, resulting in only a center portion of the barrier layer being doped. This would be repeated for each of the barrier layers until the active layer is complete.

Upon completion of the active layer, the second layer such as the p-type layer is formed at 72 and the device is completed at 74. In one embodiment, the resulting device is a double heterojunction device having a bulk active layer with much lower resistance that requires much lower voltages than would be possible without the dopants. In another embodiment, the resulting device is a multiple quantum well device having doped barrier layers, and much lower field strength across the p-n junction.

The embodiments have in common an active layer with alternating doped regions and undoped regions. In the bulk active layer embodiment, the doped regions are diffused regions of the dopant. In the quantum well embodiment, the doped regions are within the barrier layers, resulting in doped layers alternating with the quantum well layers. The doped regions do not have to be periodic or symmetric, and the doping levels at each region do not have to be uniform.

It must be noted that doping either the bulk active layers or the barrier layers within the active layer is counter to current implementations of light-emitting devices. Generally, impurities are avoided and undesirable. The process used here actively introduces impurities into the growth of the active layer, contrary to current teachings.

Other materials systems may result in application of these embodiments to other wavelengths and other types of light emitting devices. Using a gallium arsenide system rather than an aluminum nitride system may result in light emitting devices that emit light in the red and infrared range of wavelengths. Other dopants, including p-type dopants such as carbon, beryllium, and magnesium.

It will be appreciated that several of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the following claims.

What is claimed is:

1. A semiconductor light emitting device, comprising:
an n-type layer;
a p-type layer; and
a light-emitting active layer arranged between the p-type layer and the n-type layer, the active layer having alternating regions of doped and undoped materials.

2. The light emitting device of claim 1, wherein the active layer comprises a bulk active layer having regions of a doped bulk material and regions of the bulk material that are undoped.

3. The light emitting device of clam 2 wherein at least two regions are doped and a doping level of one doped region is different from a doping level of another doped region.

4. The light emitting device of claim 2, wherein the bulk material is indium aluminum gallium nitride and the doped bulk material includes silicon.

5. The light emitting device of claim 1, wherein the active layer comprises a multiple quantum well having alternating layers of a barrier material and a quantum well material, wherein at least one layer of the barrier material is further doped.

6. The light-emitting device of claim 5, wherein doping in the doped barrier layer is applied to only a first section of the barrier layer with the remaining section of the barrier layer left undoped.

7. The light-emitting device of claim 6, wherein the doped first section of the barrier layer is sandwiched between two undoped sections of the barrier layer.

8. The light-emitting device of claim 5, wherein all the barrier layers in the active layer except a barrier layer closest to the p-type layer is doped.

9. The light-emitting device of claim 5, wherein the doping level in one barrier layer is different from the doping level in another barrier layer.

10. The light emitting device of claim 5, wherein the quantum well material comprises indium aluminum gallium nitride having a first formula and the barrier material comprises indium aluminum gallium nitride having a second formula and further doped with silicon.

11. The light emitting device of claim 1, further comprising a deep-UV light emitting diode.

12. The light-emitting device of claim 1, where-in the doping is an n-type material

13. The light-emitting device of claim 1, where-in the doping is a p-type material

14. A double heterojunction light emitting device, comprising:
a bulk active layer having doped portions alternating with undoped portions.

15. The device of claim 14, wherein the bulk active layer comprises one of either an indium gallium nitride material or an aluminum gallium arsenide material.

16. The device of claim 14, wherein the doped sections comprise indium gallium nitride doped with silicon.

17. The device of claim 14, wherein the doped sections comprise aluminum gallium arsenide doped with one of carbon, beryllium, or magnesium.

18. The device of claim 14, wherein the doped sections comprise one of either n-doped or p-doped sections.

19. The device of claim 14, the light emitting device comprising an ultraviolet light emitting diode.

20. A method of manufacturing a light emitting device, comprising:
forming a first layer arranged on a substrate;
growing an active layer;
selectively adding impurities at predetermined times during the growing of the active layer; and
forming a second layer arranged on the active layer.

21. The method of claim 20, wherein growing further comprises one of either chemical vapor deposition or molecular beam epitaxy.

22. The method of claim 20, wherein selectively adding impurities further comprises turning on and off a gas during the growing.

23. The method of claim 22, wherein the gas further comprises silane gas.

24. The method of claim 20, wherein growing the active layer comprises growing a bulk material.

25. The method of claim 24, wherein selective adding impurities comprises adding impurities during growth of the bulk material.

26. The method of claim 20, wherein growing the active layer comprise growing alternating layers of a barrier material and a quantum well material.

27. The method of claim 26, wherein selectively adding impurities comprises adding impurities during growth of at least one layer of the barrier material.
